(19) United States
(12) Patent Application Publication
(10) Pub. No.: US 2006/0270106 A1
(43) Pub. Date: Nov. 30, 2006

(54) System and method for polymer encapsulated solder lid attach

(76) Inventors: Tz-Cheng Chiu, Plano, TX (US); Charles Anthony Odegard, McKinney, TX (US)

Correspondence Address: TEXAS INSTRUMENTS INCORPORATED, P O BOX 655474, M/S 3999, DALLAS, TX, 75265, US

(21) Appl. No.: 11/140,767

(22) Filed: May 31, 2005

(51) Int. Cl. H01L 21/00

(52) U.S. Cl. 438/106

(57) ABSTRACT

System and method for a polymer encapsulated solder lid attach. A preferred embodiment comprises one or more metallic islands distributed throughout the combination attach, wherein each metallic island overlays one or more heat producing portions of the integrated circuit die, and a polymer encapsulant to encircle each metallic island and to bind the one or more metallic islands in place. The one or more metallic islands, with their high thermal conductivity, can effectively dissipate large amounts of heat, while the polymer encapsulant binds the one or more metallic islands in place, preventing (or reducing) movement occurring during thermal cycles that can lead to delamination and separation.

### TECHNICAL FIELD

The present invention relates generally to a system and method for integrated circuits, and more particularly to a system and method for a polymer encapsulated solder lid attach.

### BACKGROUND

Heat dissipation requires consideration when designing packaging for integrated circuits. In high performance applications, such as microprocessors, digital signal processors, controllers for high-speed communications systems, and so forth, it is not uncommon to have to dissipate hundreds of watts of power.

A flip-chip package is commonly used for these high power applications. In a flip-chip package, a top surface of an integrated circuit die where the integrated circuits are actually formed is flipped over and directly attached to a substrate via solder bumps and a bottom surface of the integrated circuit die is typically attached to a lid that is attached to a heat sink. The heat generated by the integrated circuitry is primarily removed through the bottom surface of the integrated circuit die.

A material that has been commonly used to attach the lid to the bottom surface of the integrated circuit die is a polymer, such as an epoxy. The epoxy provides a good bond between the bottom surface of the integrated circuit die and the lid while remaining relatively compliant so that stresses due to thermal expansion do not cause delamination and separation. In some cases, particles of a metal, such as silver, can be added to the polymer to help improve the thermal conductivity of the polymer.

Another commonly used material to attach the lid to the bottom surface of the integrated circuit die is a metal, such as solder. The use of a metal can greatly increase the thermal conductive properties of the attachment material and help with heat dissipation.

One disadvantage of the prior art is that the polymer, even with the addition of the metal particles, does not have as good a thermal conductivity as a metal material. Therefore, in certain situations, the polymer may not be able to sufficiently transfer an adequate amount of heat. This can lead to an overheating of the integrated circuit die, which can lead to a failure of the integrated circuit die.

A second disadvantage of the prior art is that a metal, such as solder, is relatively inflexible. Therefore, after a relatively low number of thermal cycles, it may be possible for delamination to occur in the interface between the lid, the solder, and the integrated circuit die. When this occurs, very little to no heat can be transferred between the integrated circuit die and the heat sink and the integrated circuit die may suffer a catastrophic failure due to overheating.

### SUMMARY OF THE INVENTION

These and other problems are generally solved or circumvented, and technical advantages are generally achieved, by preferred embodiments of the present invention which provides a system and method for a polymer encapsulated solder lid attach.

In accordance with a preferred embodiment of the present invention, a combination attach for use in attaching a lid to an integrated circuit die is provided. The combination attach includes one or more metallic islands that are distributed throughout the combination attach and a polymer encapsulant that encircles each metallic island and binds the metallic island in place. The one or more metallic islands overlay one or more heat producing portions of the integrated circuit die.

In accordance with another preferred embodiment of the present invention, a method for attaching a lid to an integrated circuit die is provided. The method includes attaching the integrated circuit die to a substrate, applying a combination attach to a bottom surface of the integrated circuit die, placing the lid over the combination attach, and fixing the lid to the integrated circuit die.

In accordance with another preferred embodiment of the present invention, a packaged integrated circuit is provided. The packaged integrated circuit includes an integrated circuit die that is attached to a substrate via contacts on a top surface that also contains integrated circuitry, one or more metallic islands attached to specific portions of a bottom surface of the integrated circuit die, a lid attached to the one or more metallic islands, and a polymer encapsulant encircling each of the one or more metallic islands. The specific portions of the bottom surface of the integrated circuit die are portions that produce heat. The polymer encapsulant is attached to both the integrated circuit die and the lid.

An advantage of a preferred embodiment of the present invention is by encapsulating the metal islands in a polymer material, the different thermal characteristics of the polymer material can help to bind the metal island in place during the thermal cycles to prevent delamination and separation.

A further advantage of a preferred embodiment of the present invention is that the use of a plurality of metal islands instead of a single large monolithic sheet can help reduce the negative effects of shrinkage and expansion during a thermal cycle since the smaller dimensions of the metal islands will experience a lesser amount of shrinkage and expansion. This can further reduce the likelihood of delamination and separation.

Yet another advantage of a preferred embodiment of the present invention is that the encapsulation of the plurality of metal islands with a polymer can help to reduce the likelihood of delamination and separation since the polymer can help to bind the plurality of metal islands in place while the package experiences cool down or heat up. The binding of the plurality of metal islands can help to keep the plurality of metal islands from shifting, which could lead to delamination and separation.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b are diagrams of prior art designs for an attach used to attach a lid to an integrated circuit die;

FIGS. 2a through 2c are diagrams of combination attaches with metallic islands intended for high heat producing hot spots on an integrated circuit die, according to a preferred embodiment of the present invention;

FIG. 3 is a diagram of a cross-sectional view of a flip-chip package with a lid attached to an integrated circuit die via a combination attach, according to a preferred embodiment of the present invention;

FIG. 4 is a diagram of a cross-sectional view of a flip-chip package with a lid attached to an integrated circuit die via a combination attach, according to a preferred embodiment of the present invention;

FIG. 5 is a diagram of a preformed combination attach, according to a preferred embodiment of the present invention;

FIG. 6 is a diagram of a sequence of events in the designing of a combination attach, according to a preferred embodiment of the present invention; and

FIGS. 7a and 7b are diagrams of sequences of events in the manufacture of flip-chip packages, wherein a lid of the flip-chip package is attached to an integrated circuit die with a combination attach, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely an attach layer for use in attaching a lid to an integrated circuit die in high-power flip-chip packages. The invention may also be applied, however, to other packaging technologies wherein an integrated circuit die is attached to a surface where thermal transfer is important and the integrated circuit die is not encapsulated by a material to lock the integrated circuit die to the surface, such as in an overmolded wirebond package at an interface between the die and a lead frame pad.

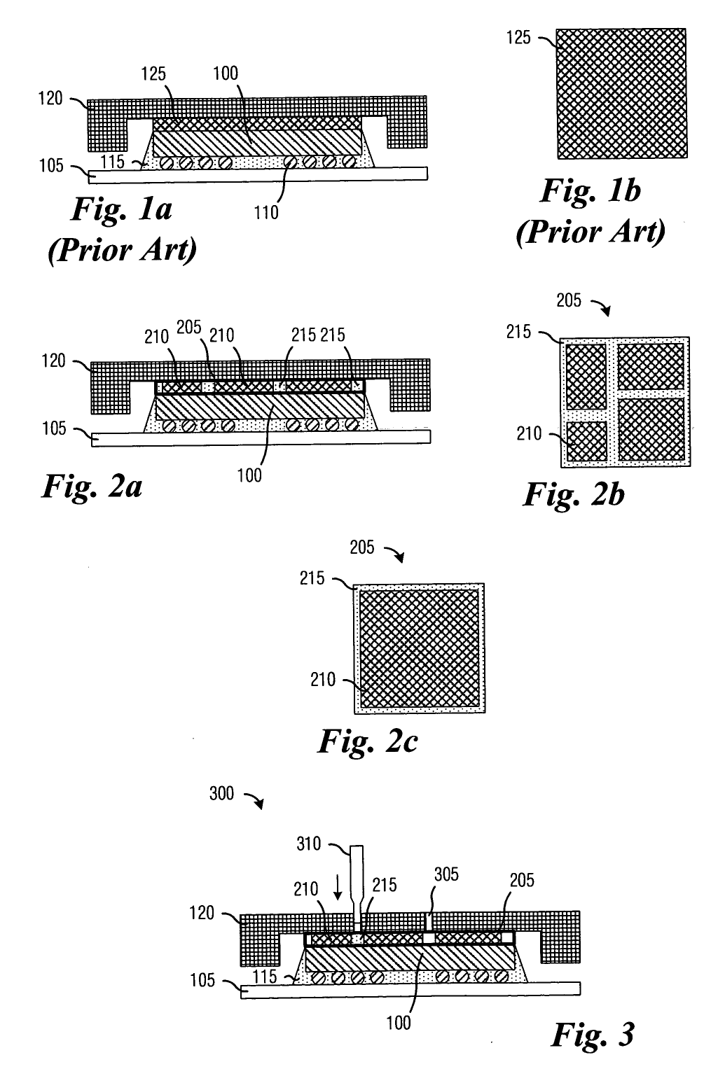

With reference now to FIGS. 1a and 1b, there are shown diagrams illustrating a prior art design of an attach for a lid and an integrated circuit die in a flip-chip package. The diagram shown in FIG. 1a illustrates a cross-sectional view of an exemplary flip-chip package. Flip-chip packaging is typically used for high-performance applications, such as micro-processors, high-speed communications system controllers, digital signal processors, and so forth, that are capable of producing large amounts of heat. In flip-chip packaging, an integrated circuit die 100 is flipped and mounted onto a substrate 105 using a plurality of electrical contacts, such as solder bumps 110. The solder bumps 110 are located on a top surface of the integrated circuit die 100, the same surface that contains integrated circuitry. Once mounted onto the substrate 105, the integrated circuit die 100 can be encapsulated by an encapsulating material to form an encapsulating layer 115. The formation of the encapsulating layer 115 can help to strengthen electrical connections between the integrated circuit die 100 and the substrate 105 as well as provide a measure of protection for the integrated circuit die 100 from its operating environment.

Since high-performance integrated circuits typically generate a large amount of heat, they require an efficient way to dissipate the heat. In a flip-chip package, the integrated circuit die 100 can be attached to a lid 120 that can have good thermal conductive properties. In many instances, a heat sink (not shown) is also attached to the lid 120 to enhance the heat dissipation qualities of the lid 120. The lid 120 can be attached to a back surface of the integrated circuit die 100, wherein the back surface of the integrated circuit die 100 is a surface of the integrated circuit die 100 that is opposite of the surface (the top surface) that contains integrated circuitry and the solder bumps 110. An attach 125 can be used to couple the lid 120 to the back surface of the integrated circuit die 100.

With reference now to FIG. 1b, a top view of the attach 125 is provided. The attach 125 is typically a monolithic entity made of a material that should have good adhesive properties as well as thermal conductance. The material chosen for the attach 125 should be able to provide a tight mechanical bond between the lid 120 and the integrated circuit die 100 as well as being able to conduct heat away from the integrated circuit die 100. Examples of materials that have been used as the attach 125 can include a polymer encapsulant, a polymer encapsulant containing metallic particles, a solder material, and so forth.

Polymer encapsulants provide good physical bonds but are not very good thermal conductors. The inclusion of metallic particles into polymer encapsulants can increase the thermal conductivity of the polymer epoxies without significantly weakening the physical bonding properties of the polymer encapsulants. Since polymer encapsulants tend to remain relatively soft and ductile, they can deform under the differential expansion and contraction that occurs in a thermal cycle. Therefore, polymer encapsulants tend to not delaminate or separate, even after a large number of thermal cycles. A metallic material, such as solder (lead or lead-free), can provide good physical bonds and excellent thermal conductivity. However, a bond formed with solder tends to be rigid and the physical bond made by the solder and between the integrated circuit die 100 and the lid 120 can be susceptible to delamination and separation due to the differential expansion and contraction that occurs in the different materials used in a flip-chip package after a relatively small number of thermal cycles. Once delamination and separation occurs, the thermal conductivity can be greatly reduced and the integrated circuit die 100 tends to rapidly self-destruct due to the inability to dissipate the heat that is generated.

Typically, an integrated circuit die will not produce the same amount of heat across its surface. A normal integrated circuit die will have hot spots on its surface that are dependent upon the circuitry located at the spots. Therefore, it may not be necessary to provide the same amount of thermal conductivity across the entire surface of the integrated circuit die. For example, in portions of the integrated circuit die that do not generate much heat, a less effective thermal conductor can be used, while in portions of the integrated circuit die that generate large amounts of heat, a highly effective thermal conductor should be used to remove as much of the heat as rapidly as possible. It is, therefore, possible to use a metallic material in the attach over portions of the integrated circuit die that generate a lot of heat, while over portions that generate little heat, a polymer encapsulant can be used in the attach. The use of the polymer encapsulant can help to restrict the expansion and contraction of the metallic portions of the attach. Additionally, the reduced size of the metallic attach can further mitigate the negative effects of thermal expansion and contraction, since the overall dimension changes during thermal expansion and contraction are smaller with the smaller metallic pieces.

With reference now to FIGS. 2a through 2c, there are shown diagrams illustrating a combination attach with metallic islands intended for high heat producing hot spots on an integrated circuit die, wherein the metallic islands are encapsulated by a polymer encapsulant, according to a preferred embodiment of the present invention. The diagram shown in FIG. 2a illustrates a cross-sectional view of an exemplary flip-chip package, wherein the lid 120 is attached to the integrated circuit die 100 with a combination attach 205. The combination attach 205 can be used to couple the lid 120 to the integrated circuit die 100 in a manner that is similar to the attach 125 (FIG. 1a). The combination attach 205 features one or more metallic islands, such as metallic island 210, which can be made from a metallic material, such as solder, and can be specifically designed to be placed over high-heat producing portions of the integrated circuit die 100. Encapsulating the metallic islands 210 can be a polymer encapsulant 215. The polymer encapsulant 215 can be made from materials such as epoxy resin or one of a wide variety of underfill materials.

The polymer encapsulant 215 can serve multiple purposes. A first purpose of the polymer encapsulant 215 is to provide a heat conduit from the integrated circuit die 100 to the lid 120 for portions of the integrated circuit die 100 not under a metallic island 210. A second purpose of the polymer encapsulant 215 is to bind the metallic island 210 in position. The binding action of the polymer encapsulant 215 can help to prevent the metallic island 210 from moving and/or shifting during expansion and contraction in a thermal cycle. This can help to eliminate (or reduce) delamination and separation of the metallic island 210 from the integrated circuit die 100 or the lid 120. The fact that the polymer encapsulant 215 can remain relatively compliant can help keep the metallic island 210 in place, even while it is expanding and contracting.

With reference now to FIG. 2b, a top view of the combination attach 205 is provided. As discussed previously, the combination attach 205 can have a plurality of metallic islands 210 that are specifically designed, sized, and placed over high-heat producing portions of the integrated circuit die 100. The plurality of metallic islands 210 can then be bound together by the binding action of the polymer encapsulant 215. According to a preferred embodiment of the present invention, the size, number, and placement of the metallic islands 210 can be determined by the nature of the integrated circuit die 100 and the physical properties of the polymer encapsulant 215. For example, the metallic islands 210 must be set a minimum distance apart to ensure that the polymer encapsulant 215 can properly flow in between the metallic islands 210 to encapsulate the metallic islands 210. Therefore, the metallic islands 210 cannot be placed closer together than a minimum distance of 20 micrometers, for example.

With reference now to FIG. 2c, a top view of the combination attach 205 is provided. The combination attach 205 features a single metallic island 210 rather than a plurality of metallic islands, such as shown in FIGS. 2a and 2b. The use of the single metallic island 210 can permit rapid implementation of the present invention since there is no need to design a layout for the plurality of metallic islands. Instead, an existing solder attach can be used (a slight reduction in size may be required to provide adequate space for the polymer encapsulant 215). The discussion herein will focus on a combination attach with a plurality of metallic islands, but a single metallic island can be readily used in their place. Therefore, the discussion of multiple metallic islands should not be construed as limiting the present invention.

With reference now to FIG. 3, there is shown a diagram illustrating a cross-sectional view of a flip-chip package 300 with a lid 120 attached to an integrated circuit die 100 via a combination attach 205, according to a preferred embodiment of the present invention. In the flip-chip package 300, as shown in FIG. 3, the lid 120 can be attached to the integrated circuit die 100 with the combination attach 205. However, when the lid 120 is attached to the integrated circuit die 100, the combination attach 205 comprises only the metallic islands 210. The polymer encapsulant 215 portion of the combination attach 205 has not been formed. The metallic islands 210 can be formed on the integrated circuit die 100 via a technique such as printing solder paste in a desired pattern directly onto the integrated circuit die 100 once it has been attached to the substrate 105.

Once the lid 120 has been attached to the integrated circuit die 100, the polymer encapsulant 215 can be deposited. According to a preferred embodiment of the present invention, the lid 120 can have one or more holes 305 that will permit a dispensing needle 310 to be inserted. The dispensing needle 310, once inserted, can deposit the polymer encapsulant 215. The polymer encapsulant 215 can then flow throughout empty voids in the combination attach 205, filling the voids. The polymer encapsulant 215, depending upon the characteristics of the material, can cure automatically or may require the application of heat.

The holes 305 in the lid 120 may be located at specific locations that can be dependent upon the layout pattern of the metallic islands 210, or they may be located at regular points on the lid 120, and depending upon the layout pattern of the metallic islands 120, some of the holes 305 may be usable for the injection of the polymer encapsulant 215 and some may not be usable due to blockage by a metallic island 120. The dispensing needle 310 can be lowered into a hole 305 and the polymer encapsulant 215 can be deposited through the dispensing needle 310. Depending upon the characteristics of the polymer encapsulant 215, the use of a single hole 305 may be adequate to dispense the polymer encapsulant 215 throughout the combination attach 205. However, multiple holes 305 can be used to ensure that the polymer encapsulant 215 is properly distributed throughout the combination attach 205. Multiple dispensing needles 310 can be used to shorten the time required to deposit the polymer encapsulant 215. The integrated circuit die 100 has already been encapsulated by the encapsulating layer 115, so the polymer encapsulant 215 can be permitted to flow freely throughout the flip-chip package 300 should it be necessary to do so to ensure that all voids in the combination attach 205 are filled.

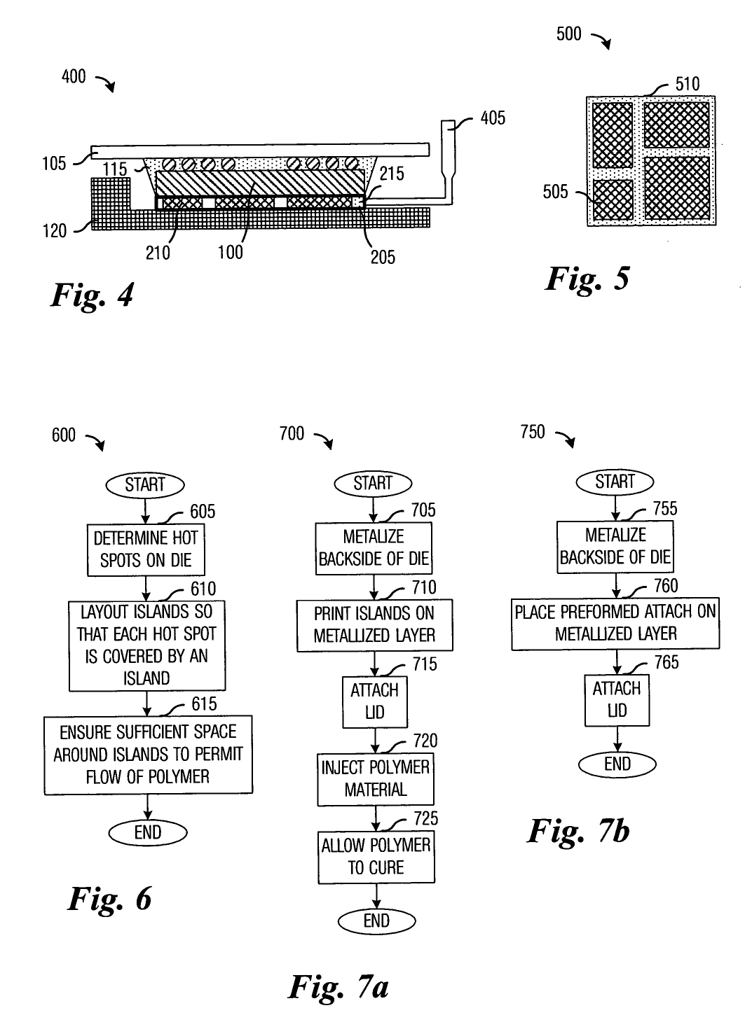

With reference now to FIG. 4, there is shown a diagram illustrating a cross-sectional view of a flip-chip package 400 with a lid 120 attached to an integrated circuit die 100 via a combination attach 205, according to a preferred embodiment of the present invention. The flip-chip package 400, as shown in FIG. 4, displays an alternate method of injecting the polymer encapsulant 215 to complete the combination attach 205. The flip-chip package 300 (FIG. 3) features holes 305 located in its lid 120 to enable the deposition of the polymer encapsulant 215. This technique may require the use of uniquely modified lids 120 for each combination attach 205 layout. Rather than having holes 305 formed into the lid 120 to permit the insertion of the dispensing needle 310, the flip-chip package 400 has an opening along a side of the flip-chip package 400 to permit the insertion of a dispensing needle 405. The dispensing needle 405 is inserted into the side of the flip-chip package 400. The opening may need to only be as large as needed to permit the insertion of the dispensing needle 405 and may not need to be as large as shown in FIG. 4.

According to a preferred embodiment of the present invention, depending upon the physical characteristics of the polymer encapsulant 215, the dispensing needle 405 can be extremely thin and can be inserted into an existing gap between the lid 120 and the substrate 105. A single design for the lid 120 can be used for a wide variety of integrated circuit dies 100 and combination attach 205 as long as the integrated circuit dies 100 and combination attach 205 can fit within the lid 120. The flip-chip package 400 may be flipped onto its lid 120 prior to the insertion of the dispensing needle 405 to have gravity assist in the dispersion of the polymer encapsulant 215.

With reference now to FIG. 5, there is shown a diagram illustrating a preformed combination attach 500, wherein the preformed combination attach 500 is manufactured in its entirety prior to use in a flip-chip package, according to a preferred embodiment of the present invention. The preformed combination attach 500 can have one or more metallic islands 505 that can be encapsulated by a polymer encapsulant 510 as in the combination attach 205 (FIG. 2). The polymer encapsulant 510 can be formed from B-stage materials (materials, namely resins, in an intermediate stage of curing), for example. However, rather than being created while it is being used, the preformed combination attach 500 can be manufactured on a separate manufacturing line prior to its use in a flip-chip package. An advantage of using a preformed combination attach 500 is that little or no modification to existing flip-chip package manufacturing lines are needed. The preformed combination attach 500 can be placed on top of a bottom surface of an integrated circuit die 100 that has already been bonded onto a substrate 105. A lid 120 can then be placed on top of the preformed combination attach 500. The flip-chip package can then be placed into an oven to create a bond between the metallic islands 505 and the lid 120 and the integrated circuit die 100. The oven can also be used to cure the polymer encapsulant material 510 to complete the encapsulation of the metallic islands 505.

With reference now to FIG. 6, there is shown a diagram illustrating a sequence of events 600 in designing a combination attach for use in a flip-chip package, according to a preferred embodiment of the present invention. The design of the combination attach for use in a flip-chip package can occur at a same time as the design of the integrated circuitry in the flip-chip package. Alternatively, the design of the combination attach can come at a time after the design of the integrated circuitry where the combination attach can be a replacement for an attach that has proven to be unsatisfactory.

The design of the combination attach can begin with a determination of hot spots on the integrated circuit die (block 605). This can be done via simulation studies of the integrated circuit die or via measurements of actual integrated circuit die. Using information regarding the hot spots, a layout for the metallic islands of the combination attach can be made (block 610). The metallic islands should be laid out so that each hot spot on the integrated circuit die is covered by a metallic island. A single metallic island can cover more than one hot spot. This may be an effective way to reduce complexity of the layout of the combination attach, especially when there are a large number of hot spots of a relatively small size. Alternatively, one single metallic island can cover the full die surface with polymer encapsulant surrounding it. In addition to having each hot spot covered by a metallic island, the layout of the combination attach should consider other layout rules such as spacing the metallic islands so that sufficient spacing exists between adjacent metallic islands so that adequate capillary action is present to enable the polymer encapsulant material to fill voids between the metallic islands, a minimum thickness for the metallic islands, and so forth (block 615). The design of the combination attach can then be used to create print screens for use with combination attaches that are made during manufacture of the flip-chip or manufacture preformed combination attaches.

With reference now to FIGS. 7a and 7b, there are shown diagrams illustrating sequences of events in the manufacture of flip-chip packages, wherein a lid of the flip-chip package is attached to an integrated circuit die with a combination attach, according to a preferred embodiment of the present invention. As shown in FIG. 7a, a sequence of events 700 can be used in the attachment of a lid to an integrated circuit die using a combination attach that can be formed on the integrated circuit die during the manufacturing process. Prior to the attachment of the combination attach, the bottom surface of the integrated circuit die may need to be metallized, such as with a chromium (Cr) film (block 705). The metallization of the bottom surface of the integrated circuit die can improve the ability of the combination attach to bind with the integrated circuit die. With the bottom surface of the integrated circuit die metallized, the metallic islands can be printed onto the bottom surface (block 710). The metallic islands can be printed using print screens made during the design of the combination attach, for example.

Once the material used for the metallic islands, such as solder paste, has had a chance to set, the lid can be placed over the metallic islands and the flip-chip packaged can be placed through an oven to melt the material used in the metallic islands and bind the lid to the integrated circuit die (block 715). After the flip-chip package has had an opportunity to cool after the binding, the polymer encapsulant material can be injected to complete the formation of the combination attach (block 720). Depending upon the design of lid, the polymer encapsulant can be injected through holes in the lid or through an opening in the side of the flip-chip package. The polymer encapsulant can then be allowed to cure (block 725), which may involve the application of heat or simply permitting the polymer encapsulant to cure at room temperature, depending upon the polymer encapsulant itself. The flip-chip package is then complete and is ready for additional testing and packaging to make it ready for distribution.

As shown in FIG. 7b, a sequence of events 750 can be used in the attachment of a lid to an integrated circuit die using a combination attach that was preformed in a separate manufacturing process. Prior to the use of the preformed combination attach, the bottom surface of the integrated circuit die may need to be metallized (block 755). Once the bottom surface of the integrated circuit die has been metallized, the preformed combination attach can be placed into position on the bottom surface of the integrated circuit die (block 760) and the lid can be lowered into position. The flip-chip package can then be placed through an oven to both melt the material used in the metallic islands in the preformed combination attach and cure the polymer encapsulant also used in the preformed combination attach to bind the lid to the integrated circuit die (block 765). The flip-chip package is then complete and is ready for additional testing and packaging to make it ready for distribution.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A combination attach for use in attaching a lid to an integrated circuit die, the combination attach comprising:
one or more metallic islands distributed throughout the combination attach, wherein each metallic island overlays one or more heat producing portions of the integrated circuit die; and
a polymer encapsulant to encircle each metallic island and to bind the metallic island in place.

2. The combination attach of claim 1, wherein the one or more metallic islands are printed onto the integrated circuit die, and wherein after the lid is attached, the polymer encapsulant is injected in between the lid and the integrated circuit die.

3. The combination attach of claim 2, wherein the polymer encapsulant is injected through one or more holes formed in the lid.

4. The combination attach of claim 3, wherein a placement of the holes is dependent upon a placement of the one or more metallic islands.

5. The combination attach of claim 2, wherein the polymer encapsulant is injected through an opening between the lid and a substrate to which the integrated circuit die is attached.

6. The combination attach of claim 2, wherein the polymer encapsulant is an underfill material.

7. The combination attach of claim 1, wherein the combination attach is a single unit, and wherein the polymer encapsulant is a B-stage material.

8. The combination attach of claim 1, wherein the one or more metallic islands are made from a solder material.

9. A method for attaching a lid to an integrated circuit die, the method comprising:
attaching the integrated circuit die to a substrate;
applying a combination attach to a bottom surface of the integrated circuit die;
placing the lid over the combination attach; and
fixing the lid to the integrated circuit die.

10. The method of claim 9, wherein the applying comprises printing one or more metallic islands onto the bottom surface of the integrated circuit die.

11. The method of claim 10, wherein the fixing comprises placing the integrated circuit die and the lid in an oven for a period of time and at a specific temperature to allow the one or more metallic islands to attach to the lid and the integrated circuit die.

12. The method of claim 10 further comprising after the fixing:
injecting a polymer encapsulant into the lid to encapsulate the one or more metallic islands; and
curing the polymer encapsulant.

13. The method of claim 12, wherein the injecting comprises using a dispensing needle.

14. The method of claim 13, wherein the injecting comprises injecting the polymer encapsulant through holes in the lid.

15. The method of claim 13, wherein the injecting comprises injecting the polymer encapsulant through an opening between the substrate and the lid.

16. The method of claim 9, wherein the applying comprises placing a preformed combination attach onto the bottom surface of the integrated circuit die.

17. The method of claim 16, wherein the combination attach comprises one or more metallic islands and a polymer encapsulant encircling each metallic island, and wherein the fixing comprises placing the integrated circuit die, the combination attach, and the lid in an oven for a period of time and at a specific temperature to allow the one or more metallic islands to attach to the lid and the integrated circuit die and the polymer encapsulant to cure.

18. A packaged integrated circuit comprising:
an integrated circuit die having a top surface containing integrated circuitry, the integrated circuit die attached to a substrate via contacts on the top surface;
one or more metallic islands attached to specific portions of a bottom surface of the integrated circuit die, wherein the specific portions of the bottom surface are portions of the integrated circuit die that produce heat;
a lid attached to the one or more metallic islands; and
a polymer encapsulant encircling each of the one or more metallic islands, the polymer encapsulant attached to both the integrated circuit die and the lid.

19. The packaged integrated circuit of claim 18, wherein the lid has one or more holes to allow a dispensing of the polymer encapsulant.

20. The packaged integrated circuit of claim 18, wherein an opening exists between the substrate and the lid, the opening to allow a dispensing of the polymer encapsulant.
